(19) United States
(12) Patent Application Publication
(10) Pub. No.: US 2011/0186129 A1
(43) Pub. Date: Aug. 4, 2011

(54) PHOTOVOLTAIC APPARATUS FOR DIRECT CONVERSION OF SOLAR ENERGY TO ELECTRICAL ENERGY

(75) Inventor: Andreas Gombert, Freiburg (DE)

(73) Assignee: CONCENTRIX SOLAR GMBH, Freiburg (DE)

(21) Appl. No.: 13/056,634

(22) PCT Filed: Jul. 30, 2009
(86) PCT No.: PCT/EP2009/005540

§ 371 Date: Apr. 19, 2011

(30) Foreign Application Priority Data
Jul. 30, 2008 (DE) 10 2008 035 575.5

(51) Int. Cl. H01L 31/0232; H01L 31/024

(52) U.S. Cl. 136/259

(57) ABSTRACT

A photovoltaic apparatus for directly converting solar energy into electrical energy. The apparatus can include a concentrator optics arrangement configured to reduce a transmission of the solar energy at wavelengths of less than or equal to about 350 nm by at least approximately 50%; at least one solar cell; and at least one heat sink.

### CROSS-REFERENCE TO PRIOR APPLICATIONS

This application is the U.S. National Stage Application of International Application No. PCT/EP2009/005540, filed on Jul. 30, 2009, which was published as WO 2010/012474 on Feb. 4, 2010, and claims priority to German Patent Application No. 10 2008 035 575.5, filed on Jul. 30, 2008. The disclosures of the above-referenced applications are incorporated by reference herein in their entireties.

### FIELD

The present disclosure relates to a photovoltaic apparatus for direct conversion of solar energy into electrical energy, and specifically to a photovoltaic apparatus including two optics used to facilitate two-stage concentration of the sunlight such that a transmission of sunlight at wavelengths 350 nm is reduced by at least 50%.

### BACKGROUND

In the field of concentrator photovoltaics (CPV), the directly incident solar radiation is typically concentrated onto a solar cell by concentrator optics, so that the irradiation intensity on the cell is increased by the so-called concentration factor [A. Luque and V. Andreev (Eds.), Concentrator Photovoltaics, Springer Series in Optical Sciences 130, SpringerVerlag, Berlin Heidelberg (2007)]. Within the design of the concentrator optics, there are a large number of optical approaches, which are normally based on refraction, reflection or total internal reflection on optical components having a special shape [P. Benitez and J. C. Minano “Concentrator optics for the next-generation photovoltaics”, in A. Marti and A. Luque (Ed.), “Next Generation Photovoltaics”, Institute of Physics Publishing, Series in Optics and Optoelectronics, Bristol and Philadelphia, ISBN 0750309059, 2004]. In high concentration systems, it is also common practice to effect optical concentration in two steps by a primary and a secondary concentrator. The secondary concentrator, in turn, can have different structural designs making use of the above-mentioned optical effects. For example, it can be used for increasing the concentration, for enlarging the angular field over which the solar cell receives radiation, and for distributing the radiation more homogeneously over the cell area. When solid secondary concentrators including a transparent material are used, it is normally preferable to optically couple the secondary concentrator to the solar cell. In total, such an optical system has geometric concentrations (input area/solar cell area) from several hundred to a few thousand. Taking additionally into account the inhomogeneity of the irradiation intensity, the locally incident solar radiation may, after concentration, have irradiation intensities which, at a maximum, exceed those of non-concentrated solar radiation incident on the earth by far more than a thousand. This can be a challenge especially with respect to the UV stability of the materials used in the vicinity of the solar cell, since, without filtering the UV radiation in the UV range of the solar radiation, UV irradiation intensities of >5 W/cm² may occur. Over the long periods of use of concentrator photovoltaic modules, these UV irradiation intensities may lead to solarization and, in combination with the existing atmospheric oxygen, to a photo-oxidation of the materials irradiated. In addition, moisture in the module may increase the degradation. Special loads occur in connection with the normally used sealing of III-V multi-junction solar cells, which are typically sensitive to moisture, or in connection with the layer used for optically coupling a solid secondary concentrator. The sealing materials are typically silicone resins or organic-inorganic hybrid polymers or highly cross-linked polymers, which have been highly cross-linked by an introduction of energy in the form of electron radiation or UV radiation or by plasma discharge. The material used for the optical coupling layer has, up to now, has primarily been silicone resin.

In existing systems, the transparent resin, which is used for optically coupling the secondary concentrator and for protecting the solar cell against moisture, can be protected against sunlight by a shielding member, e.g. a non-transparent resin, [Araki et al., “Concentrator solar photovoltaic power generating apparatus”, patent US 2008/0087323 A1].

A drawback of the above solution is that it is, difficult to introduce into the optical beam path a protection against solar radiation in general, since it is the task of the photovoltaic system to convert this radiation with the highest possible efficiency. The shielding member described in Araki et al. would therefore strongly attenuate the solar radiation incident on the active reception area of the solar cell, if it were provided in the beam path, and would thus markedly reduce the efficiency of the solar generator. This is the reason for the fact that the area outside the beam path is protected by the shielding member in the case of this known solution.

### SUMMARY

An aspect of the present disclosure can protect UV radiation-sensitive components of a concentrator photovoltaic module against the UV radiation density in the beam path, which increases as the concentration of the sunlight increases. Another aspect of the present disclosure can prevent the radiation which is convertible by the solar cell from being attenuated to such an extent that the efficiency will decrease markedly.

### BRIEF DESCRIPTION OF THE DRAWINGS

With reference to the following FIGURE, the subject matter according to the present disclosure is to be illustrated more in detail without wanting to restrict the same to the exemplary embodiments shown herein.

FIG. 1 shows a schematic illustration of the structural design of a photovoltaic apparatus according to an exemplary embodiment of the present disclosure.

### DETAILED DESCRIPTION

According to exemplary embodiments of the present disclosure, a photovoltaic apparatus for direct conversion of solar energy into electrical energy can be provided, which includes single-stage or two-stage concentrator optics including a plurality of elements, as well as at least one solar cell (40) and a heat sink (50). The materials of the elements of the concentrator optics are adapted to one another in such a way that the concentrator optics reduce the transmission of sunlight at wavelengths of ≦approximately 350 nm by at least approximately 50%.

The concentrator optics preferably include a cover plate, primary optics and secondary optics, the optics effecting a two-stage concentration of the sunlight.

According to an exemplary embodiment, the concentrator optics include at least one radiation absorber.

The radiation absorber is preferably arranged in the regions of the concentrator optics in which a concentration of sunlight has not yet taken place, or only taken place to a minor extent, since degradation processes are often subjected to thresholds of irradiation intensities or the absorption would lead to an excessive generation of heat in the case of high concentrations of the UV radiation.

On the other hand, the components which are subjected to a particularly high UV radiation load are those that are exposed to a particularly high concentration. These are, e.g., the areas between the solar cell and the secondary optics, a layer for effecting optical coupling being normally provided between these two elements.

According to another exemplary embodiment, a protective coating is deposited on the surface of the cover plate facing the sunlight.

Preferably, the cover plate, which can be made, e.g., of glass, is arranged directly on the primary optics, which include, e.g., a silicone resin. It is, however, also possible that the cover plate and the primary optics have disposed between them a connection layer, at least in certain areas. This connection layer is preferably a laminate-forming or an adhesive layer. The connection layer is preferably selected from the group including ethylene vinyl acetate, polyvinyl butyral, acrylate-based adhesive layers, or hotmelt adhesives, such as polyamides, polyethylene, amorphous polyalpha olefins, polyester elastomers, polyurethane elastomers, co-polyamide elastomers, vinyl pyrrolidone/vinyl acetate copolymers, or polyester resins, polyurethane resins, epoxy resins, silicone and vinylester resins.

The primary optics preferably includes a micro-replicated Fresnel lens or of an optical element based on the Fresnel principle. Suitable materials can include thermoplastic materials, such as, e.g., thermosetting materials, thermoplastic elastomers or elastomers. Other preferred materials include silicone resins, polymethyl methacrylates, acrylate lacquers, polyurethane lacquers and dual cure lacquers, i.e. lacquers based on a combination of radical cross-linking and isocyanate cross-linking.

With respect to the secondary optics, there are two preferred exemplary embodiments. In one exemplary embodiment, the secondary optics include a solid body made of a transparent material. Suitable materials preferably include inorganic glass, organic glass or transparent polymers. Such solid secondary optics can be preferably provided with an additional coating on the surface facing the sunlight.

It is, however, also possible that the secondary optics surface facing the sunlight is modified using a wet-chemical or dry-chemical etching processes, so that the surface can be used as a radiation absorber. Such a modified surface is preferably created through etching of transparent polymers in a dry-etching step using plasma under reduced pressure or under atmospheric pressure. In the case of this etching process, precursors may be added, e.g., in a plasma CVD process, which can result in a specific chemical modification of the layer.

Another exemplary embodiment of the secondary optics according to the present disclosure can include a reflective secondary optics configured as a hollow body. In this embodiment, the reflective secondary optics preferably have, at least in certain areas thereof, an interior coating, e.g., a coating facing the hollow space.

According to another exemplary embodiment, a coating used for effecting optical coupling can be arranged between the solid secondary optics and the solar cell.

Exemplary embodiments of the present can provide that radiation absorbers are preferably arranged in the cover plate, the primary optics, the secondary optics, the above-described protective coating, the connection layer, the coating of the secondary optics on the surface facing the sunlight, the coating used for effecting optical coupling between the secondary optics and the solar cell, or the interior coating. It is also possible that radiation absorbers are arranged in a plurality of, or in all these components. Preferably, the trans-mission of sunlight at wavelengths approximately 350 nm is to be reduced by at least approximately 50%.

The materials used for the radiation absorbers are preferably organic materials, and can be selected from the group include oxanilides, benzotriazoles, benzophenones, hydroxyl-phenyl-triazines, sterically hindered amines (HALS) or mixtures thereof. Also inorganic materials are preferred, one of the inorganic materials can include titanium dioxide nanoparticles.

The coating used for effecting optical coupling between the secondary optics and the solar cell is preferably made of silicone or of transparent polymers, in particular organic-inorganic hybrid polymers.

The interior coating of the secondary optics configured as a hollow body preferably includes TiOₓ, SnOₓ or ZnOₓ cover layers on a carrier layer or a carrier substrate of silver or aluminum.

The cover plate preferably includes glass, and in particular of Cer-doped glass, borosilicate glass or soda lime glass.

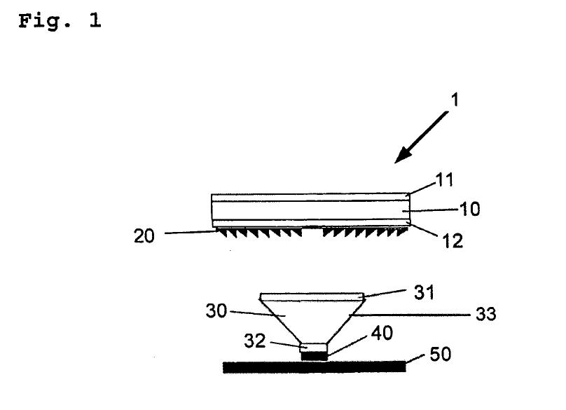

An embodiment of the photovoltaic apparatus (1) according to the present disclosure is shown in FIG. 1 and is described below:

An exemplary apparatus can include a coating 11 include a UV absorbent, inorganic nanoparticles, e.g., TiO₂ particles. These nanoparticles are preferably applied as a porous network of liquid precursors, e.g., by a sol-gel technique—where appropriate in combination with SiO₂ nanoparticles—in such a way that the layer optically represents an effective medium having an effective index of refraction between about 1.3 and about 1.5.

The exemplary apparatus can also include a Cer-doped glass pane 10, and a micro-replicated primary concentrator 20 including thermoplastic materials, thermosetting materials, elastomers (such as especially silicones) and thermoplastic elastomers, which were formed in embossing or casting processes with or without radiation curing on backing films or without any backing materials with a tool having the negative shape of the Fresnel lens-like optical element, and which are provided with UV absorbent characteristics according to embodiments of the present disclosure. Preferred materials include silicone resins, polymethyl methacrylates or cross-linking systems, such as acrylate lacquers. According to an exemplary embodiment, the Fresnel lens-like optical system can be replicated in an acrylate layer on a backing film in a continuous replication process using a cylindrical tool, or a tool fixed in position on a cylinder, and with radiation curing. In this case, the acrylate layer as well as the backing film can have UV absorbent characteristics.

The exemplary apparatus can further include an adhesive- or laminate-forming layer 12, including, e.g., ethylene vinyl acetate, polyvinyl butyral (PVB), acrylate-based adhesive layers, hotmelt adhesives (hotmelts), such as polyamides, polyethylene, amorphous polyalpha olefins, polyester elastomers, polyurethane elastomers, co-polyamide elastomers, vinyl pyrrolidone/vinyl acetate copolymers, polyester resins, polyurethane resins, epoxy resins, silicone and vinylester resins. Preferably, they include UV absorbent characteristics according to embodiments of the present disclosure.

An embodiment can include a solid secondary concentrator including inorganic glass, a coating 31 containing UV absorbent inorganic nanoparticles, e.g., TiO₂ nanoparticles. These nanoparticles are preferably applied as a porous network of liquid precursors, e.g., by a sol-gel technique—where appropriate in combination with SiO₂ nanoparticles—in such a way that the layer optically represents an effective medium having an effective index of refraction between about 1.3 and about 1.5.

Another exemplary embodiment can include a solid secondary concentrator including organic glass, a coating 31 containing UV absorbent organic components or as an inorganic-organic hybrid polymer also inorganic absorbers, such as TiO₂ nanoparticles. Layers having indices of refraction between approximately 1.3 and approximately 1.5 are preferably used.

Another exemplary embodiment can include a solid secondary concentrator 30 including transparent inorganic glass or of a transparent polymer having a suitable UV absorbent characteristics. The secondary concentrator including glass is preferably produced by blank moulding, and here preferably in a parallelized process. When the material in question is a transparent polymer, injection moulding is preferably used, and materials which are preferable in this case include silicones provided with UV absorbent characteristics. An exempalry embodiment of the present disclosure can include also a coating 32 and an interior coating 33.

Another exemplary embodiment can include a reflective secondary concentrator 30 configured as a hollow body whose interior coating is provided with UV absorbent characteristics. Coatings that are suitable for this purpose can include, e.g., TiOₓ, SnOₓ— or ZnO, cover layers on an Ag or Al layer or on an Al substrate. The UV absorption can additionally be adjusted through the stoichiometry of the cover layers.

While an illustrative embodiment of the invention has been disclosed herein, it will be appreciated that numerous modifications and other embodiments may be devised by those skilled in the art. Therefore, it will be understood that the appended claims are intended to cover all such modifications and embodiments that come within the spirit and scope of the present invention.

1-20. (canceled)

21. A photovoltaic apparatus for directly converting solar energy into electrical energy, comprising:
a concentrator optics arrangement configured to reduce a transmission of the solar energy at wavelengths of less than or equal to about 350 nm by at least approximately 50%; and
at least one solar cell coupled to the concentrator optics arrangement and configured to receive and directly convert the solar energy into electrical energy.

22. The apparatus of claim 21, further comprising a heat sink.

23. The apparatus of claim 21, wherein the concentrator optics arrangement is one of a single-stage concentrator optics arrangement or a two-stage concentrator optics arrangement.

24. The apparatus of claim 21, wherein the concentrator optics arrangement includes a first optics arrangement, and a second optics arrangement, and wherein the first and second optics arrangement are configured as a two-stage concentrator for the solar energy.

25. The apparatus of claim 21, wherein the concentrator optics arrangement includes a radiation absorber configured to reduce the transmission of the solar energy at wavelengths of less than or equal to about 350 nm by at least approximately 50%.

26. The apparatus of claim 25, wherein the radiation absorber is disposed in a portion of the apparatus having a low concentration of the solar energy.

27. The apparatus of claim 24, further comprising a laminate-forming or adhesive connection layer disposed between a cover plate and the first optics arrangement.

28. The apparatus of claim 24, wherein the second optics arrangement includes a transparent material.

29. The apparatus of claim 28, wherein the transparent material includes at least one of an inorganic glass, an organic glass, or a transparent polymer.

30. The apparatus of claim 29, wherein the second optics arrangement includes a radiation absorptive coating disposed on a surface facing the solar energy.

31. The apparatus of claim 30, wherein the surface facing the solar energy is treated using at least one of a wet-chemical etching process or a dry-chemical etching process so as to make the surface radiation absorbent.

32. The apparatus of claim 31, wherein the transparent material includes a transparent polymer, and the transparent polymer treatment includes a plasma dry-etch under atmospheric pressure or lower.

33. The apparatus of claim 24, wherein the second optics arrangement includes a reflective hollow body having a radiation absorptive coating disposed on at least a portion of an interior surface.

34. The apparatus of claim 24, further comprising a coating configured to effect optical coupling disposed between the second optics arrangement and the solar cell.

35. The apparatus of claim 24, wherein the radiation absorber includes at least one of a cover plate, the first optics arrangement, the second optics arrangement, a first coating disposed on a surface of a cover plate facing the solar energy, a connection layer disposed between the cover plate and the first optics arrangement, a second coating disposed on a surface of the second optics arrangement facing the solar energy, a third coating configured to effect optical coupling disposed between the second optics arrangement and the solar cell, or a fourth coating disposed on at least a portion of an interior surface of the second optics arrangement includes a coating.

36. The apparatus of claim 24, wherein at least one of a first coating disposed on a surface of a cover plate facing the solar energy or a second coating disposed on a surface of the second optics arrangement facing the solar energy includes an index of refraction between about 1.3 and about 1.5.

37. The apparatus of claim 25, wherein the radiation absorber includes at least one of an oxanilide, a benzotriazole, a benzophenone, a hydroxyl-phenyl-triazine, a sterically hindered amines (HALS), or mixtures thereof.

38. The apparatus of claim 25, wherein the radiation absorber includes a titanium dioxide nanoparticle.

39. The apparatus of claim 24, wherein the first optics arrangement includes a Fresnel lens.

40. The apparatus of claim 39, wherein the Fresnel lens includes a micro-replicated Fresnel lens.

41. The apparatus of claim 39, wherein the Fresnel lens includes at least one of a thermoplastic material, a thermosetting material, a thermoplastic elastomer, or an elastomer.

42. The apparatus of claim 39, wherein the Fresnel lens includes at least one of a silicone resin, a polymethyl methacrylate, an acrylate lacquer, a polyurethane lacquer, or a dual cure lacquer.

43. The apparatus of claim 27, wherein the connection layer includes at least one of an ethylene vinyl acetate, a polyvinyl butyral, an acrylate-based adhesive layer, a hot-melt adhesive, a polyamide, a polyethylene, an amorphous polyalpha olefin, a polyester elastomer, a polyurethane elastomer, a co-polyamide elastomer, a vinyl pyrrolidone/vinyl acetate copolymer, a polyester resin, a polyurethane resin, an epoxy resin, a silicone or a vinylester resin.

44. The apparatus of claim 34, wherein the coating includes at least one of a silicone, a transparent polymer, or an organic-inorganic hybrid polymer.

45. The apparatus of claim 34, wherein the coating includes a cover layer disposed on a carrier layer or a carrier substrate of silver or aluminum, the coating layer having at least one of TiOx, SnOx or ZnOx.

46. The apparatus of claim 21, further comprising a cover plate including a glass, the glass having at least one of a Cer-doped glass, a borosilicate glass, or a soda lime glass, and the cover plate includes a protective coating disposed on a surface facing the solar energy.
